(19) United States
(12) Patent Application Publication
(10) Pub. No.: US 2024/0321683 A1
(43) Pub. Date: Sep. 26, 2024

(54) SEMICONDUCTOR PACKAGE AND COOLING SYSTEM THEREOF

(71) Applicant: Samsung Electronics Co., Ltd., Suwon-si (KR)

(72) Inventor: Jinwoo PARK, Suwon-si (KR)

(73) Assignee: Samsung Electronics Co., Ltd., Suwon-si (KR)

(21) Appl. No.: 18/428,033

(22) Filed: Jan. 31, 2024

(30) Foreign Application Priority Data
Mar. 24, 2023 (KR) 10-2023-0039242
May 3, 2023 (KR) 10-2023-0057775

(51) Int. Cl. H01L 23/473; H01L 23/00; H01L 25/065

(52) U.S. Cl. CPC H01L 23/473; H01L 24/16; H01L 24/32; H01L 24/73; H01L 25/0652; H01L 2224/16225; H01L 2224/32145; H01L 2224/73253; H01L 2924/1431; H01L 2924/181

(57) ABSTRACT

A semiconductor package may include a semiconductor chip, a dummy semiconductor chip on the semiconductor chip;, and a bonding insulating layer between the semiconductor chip and the dummy semiconductor chip. The bonding insulating layer may attach the semiconductor chip to the dummy semiconductor chip. The dummy semiconductor chip may include a cooling channel extending from an inlet to an outlet. The inlet may be in fluid communication with the outlet through the cooling channel. The inlet may be configured to allow a cooling fluid to flow in. The outlet may be configured to allow the cooling fluid to flow out. A top surface of the bonding insulating layer may have a concave-convex shape.

### CROSS-REFERENCE TO RELATED APPLICATIONS

This application is based on and claims priority under 35 U.S.C. § 119 to Korean Patent Application Nos. 10-2023-0039242, filed on Mar. 24, 2023 and 10-2023-0057775, filed on May 3, 2023, in the Korean Intellectual Property Office, the disclosures of each of which are incorporated by reference herein in their entirety.

### BACKGROUND

Inventive concepts relate to a semiconductor package and a cooling system thereof, and more particularly, to a system-in-package, in which different kinds of semiconductor chips are included in a single semiconductor package, and a cooling system thereof.

With the rapid increase in demand for portable devices in the recent electronic products market, electronic components mounted on electronic products have continuously been required to be compact and light. To make electronic components compact and light, a semiconductor package mounted on the electronic components is required to be small in volume and to process a large amount of data. There is also a demand for high integration and single packaging of semiconductor chips mounted on such a semiconductor package. Accordingly, a system-in-package is used to efficiently arrange semiconductor chips in the limited structure of a semiconductor package, and technology for cooling the semiconductor package is proposed.

### SUMMARY

Inventive concepts provide a semiconductor package capable of cooling using a cooling fluid and a cooling system of the semiconductor package.

According to an embodiment of inventive concepts, a semiconductor package may include a semiconductor chip, a dummy semiconductor chip on the semiconductor chip, and a bonding insulating layer between the semiconductor chip and the dummy semiconductor chip. The bonding insulating layer may attach the semiconductor chip to the dummy semiconductor chip. The dummy semiconductor chip may include a cooling channel extending from an inlet to an outlet. The inlet may be in fluid communication with the outlet through the cooling channel. The inlet may be configured to allow a cooling fluid to flow in. The outlet may be configured to allow the cooling fluid to flow out. A top surface of the bonding insulating layer may have a concave-convex shape.

According to an example embodiment of inventive concepts, a semiconductor package may include an interposer, a first semiconductor chip on the interposer, at least one second semiconductor chip on the interposer and separated from the first semiconductor chip in a horizontal direction, a dummy semiconductor chip on the first semiconductor chip, and a bonding insulating layer between the first semiconductor chip and the dummy semiconductor chip. The bonding insulating layer may attach the first semiconductor chip to the dummy semiconductor chip. The dummy semiconductor chip may include a cooling channel extending from an inlet to an outlet. The inlet may be in fluid communication with the outlet through the cooling channel. The inlet may be configured to allow a cooling fluid to flow in. The outlet may be configured to allow the cooling fluid to flow out. A bottom surface of the cooling channel may be in contact with a top surface of the bonding insulating layer.

According to an embodiment of inventive concepts, a semiconductor package may include a package substrate; an interposer on the package substrate; a first semiconductor chip on the interposer; at least one second semiconductor chip on the interposer and separated from the first semiconductor chip in a horizontal direction; a dummy semiconductor chip on the first semiconductor chip; a bonding insulating layer between the first semiconductor chip and the dummy semiconductor chip, the bonding insulating layer attaching the first semiconductor chip to the dummy semiconductor chip; and a molding layer on the interposer, the molding layer surrounding the first semiconductor chip, the at least one second semiconductor chip, the dummy semiconductor chip, and the bonding insulating layer. The dummy semiconductor chip may include a cooling channel extending from an inlet to an outlet. The inlet may be in fluid communication with the outlet through the cooling channel. The inlet may be configured to allow a cooling fluid to flow in. An outlet may be configured to allow the cooling fluid to flow out. A top surface of the bonding insulating layer may have a concave-convex shape.

### BRIEF DESCRIPTION OF THE DRAWINGS

Embodiments will be more clearly understood from the following detailed description taken in conjunction with the accompanying drawings in which:

FIG. 1A is a cross-sectional view of a semiconductor package according to an embodiment, FIG. 1B is a plan view of a semiconductor package according to an embodiment, and FIG. 1C is a plan view of a dummy semiconductor chip according to an embodiment;

FIG. 2 is a cross-sectional view illustrating a cooling system of a semiconductor package according to an embodiment;

FIG. 3A is a cross-sectional view of a semiconductor package according to an embodiment and FIG. 3B is a plan view of a dummy semiconductor chip according to an embodiment;

FIG. 4A is a cross-sectional view of a semiconductor package according to an embodiment and FIG. 4B is a plan view of a dummy semiconductor chip according to an embodiment;

FIG. 5 is a plan view of a dummy semiconductor chip according to an embodiment;

FIG. 6 is a plan view of a dummy semiconductor chip according to an embodiment;

FIG. 7 is a plan view of a dummy semiconductor chip according to an embodiment;

FIG. 8 is a plan view of a dummy semiconductor chip according to an embodiment; and

FIGS. 9A to 9E are cross-sectional views of stages in a method of manufacturing a semiconductor package, according to an embodiment.

### DETAILED DESCRIPTION

As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C” and “at least one of A, B, or C”) may be construed as A only, B only, C only, or any combination of two or more of A, B, and C, such as, for instance, ABC, AB, BC, and AC.

Hereinafter, embodiments are described in detail with reference to the accompanying drawings. In the drawings, like numerals denote like elements and redundant descriptions thereof will be omitted.

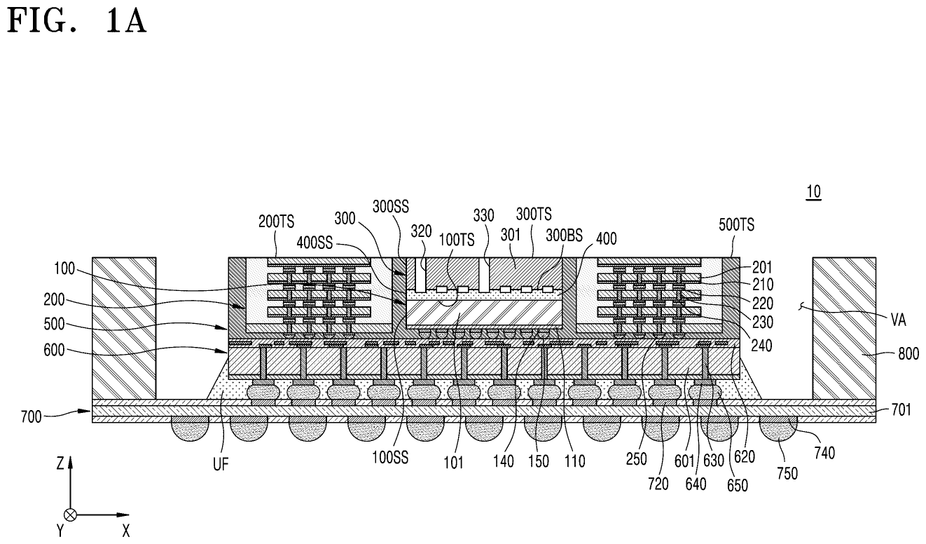

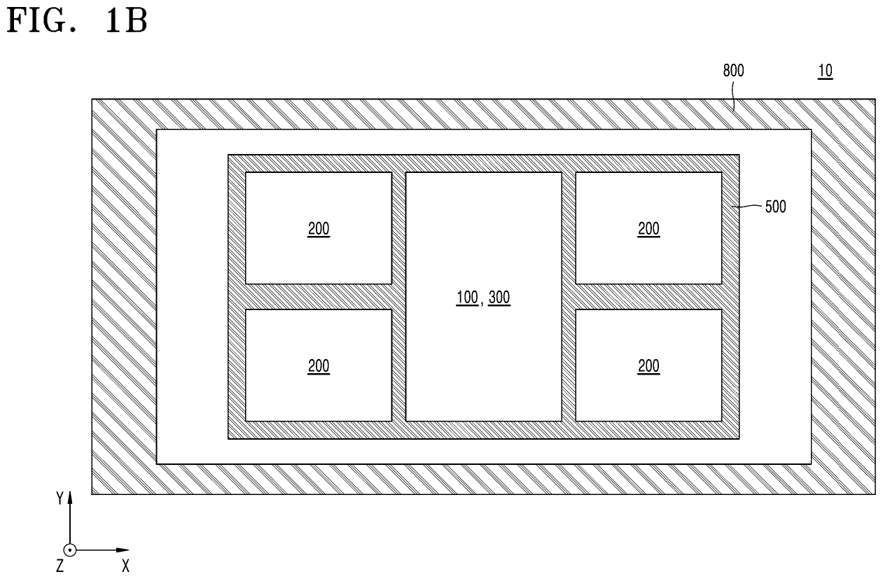

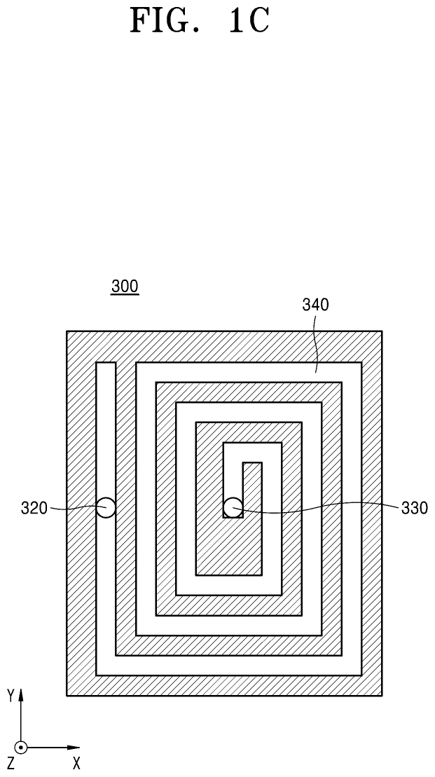

FIG. 1A is a cross-sectional view of a semiconductor package according to an embodiment, FIG. 1B is a plan view of a semiconductor package according to an embodiment, and FIG. 1C is a plan view of a dummy semiconductor chip according to an embodiment. To clearly show the arrangement relationship among elements, FIG. 1B illustrates only a first semiconductor chip 100, a second semiconductor chip 200, a dummy semiconductor chip 300, a molding layer 500, and a reinforcing structure 800.

Referring to FIGS. 1A to IC, a semiconductor package 10 may include the first semiconductor chip 100, the second semiconductor chip 200, the dummy semiconductor chip 300, a bonding insulating layer 400, the molding layer 500, an interposer 600, a package substrate 700, and the reinforcing structure 800.

The semiconductor package 10 may include the first semiconductor chip 100 and the second semiconductor chip 200, which perform different functions. The semiconductor package 10 may include at least one first semiconductor chip 100 and at least one second semiconductor chip 200. The first and second semiconductor chips 100 and 200 may be side by side in a first horizontal direction (e.g., the X direction) and/or a second horizontal direction (e.g., the Y direction) and may be electrically connected to each other by the interposer 600. As shown in FIG. 1B, four second semiconductor chips 200 may be around one first semiconductor chip 100. In other words, two second semiconductor chips 200 may be arranged near one edge of a top surface 100TS of the first semiconductor chip 100 and two second semiconductor chips 200 may be arranged near another edge of the top surface 100TS of the first semiconductor chip 100.

Here, the horizontal direction (the X direction and/or the Y direction) may refer to a direction parallel with a main surface of the package substrate 700 and the vertical direction (the Z direction) may refer to a direction perpendicular to the horizontal direction (the X direction and/or the Y direction).

In addition, the top surface of any element other than an external connection terminal 750 may refer to a surface of the element further away from the external connection terminal 750 in the vertical direction (the Z direction) between two surfaces of the element separated from each other in the vertical direction (the Z direction) and the bottom surface of the element may refer to a surface thereof which is opposite to the top surface of the element. The top surface of the external connection terminal 750 may refer to a surface thereof which is in contact with a bump pad 740.

The first semiconductor chip 100 may include a logic chip. The logic chip may include a plurality of logic devices (not shown). The logic devices may include logic circuits, such as an AND circuit, an OR circuit, a NOT circuit, and a flip-flop, and perform various kinds of signal processing. In some embodiments, the logic devices may perform signal processing, such as analog signal processing, analog-to-digital conversion (ADC), and signal control.

In some embodiments, the first semiconductor chip 100 may be embodied as a microprocessor, a graphics processor, a signal processor, a network processor, a chipset, an audio codec, a video codec, an application processor, a system-on-chip (SoC), or the like, according to the function thereof. The first semiconductor chip 100 may include processing circuitry.

The second semiconductor chip 200 may include a volatile memory chip and/or a non-volatile memory chip. For example, the volatile memory chip may include dynamic random access memory (DRAM), static RAM (SRAM), or thyristor RAM (TRAM). For example, the non-volatile memory chip may include flash memory, magnetic RAM (MRAM), spin-transfer torque MRAM (STT-MRAM), ferroelectric RAM (FRAM), phase-change RAM (PRAM), or resistive RAM (RRAM). The second semiconductor chip 200 may include processing circuitry.

In some embodiments, the second semiconductor chip 200 may be configured as a memory chiplet including a plurality of memory chips capable of data merging with each other. The second semiconductor chip 200 may include a high-bandwidth memory (HBM) chip. In other words, the semiconductor package 10 including the first and second semiconductor chips 100 and 200 may correspond to HBM, the first semiconductor chip 100 may be referred to as an HBM controller die, and the second semiconductor chip 200 may be referred to as a DRAM die.

Elements of each of the first and second semiconductor chips 100 and 200 are described in detail below.

The first semiconductor chip 100 may include a first semiconductor substrate 101, a first semiconductor wiring layer 110, a first connection pad 140, and a first connection member 150.

The first semiconductor chip 100 may include a single slice. The single slice may be configured as the first semiconductor substrate 101. The first semiconductor substrate 101 may correspond to a wafer and include an active surface and an inactive surface facing the active surface. Here, the inactive surface of the first semiconductor substrate 101 may correspond to the top surface 100TS of the first semiconductor chip 100, which is further away from the interposer 600 than the bottom surface of the first semiconductor chip 100.

For example, the first semiconductor substrate 101 may correspond to a silicon wafer including crystalline silicon, polycrystalline silicon, or amorphous silicon. Alternatively, the first semiconductor substrate 101 may include a semiconductor element, such as germanium (Ge), or a compound semiconductor, such as silicon carbide (SiC), gallium arsenide (GaAs), indium arsenide (InAs), or indium phosphide (InP).

The first semiconductor substrate 101 may have a silicon-on-insulator (SOI) structure. For example, the first semiconductor substrate 101 may include a buried oxide layer (BOX). In some embodiments, the first semiconductor substrate 101 may include, for example, an impurity-doped well or an impurity-doped structure. The first semiconductor substrate 101 may have various isolation structures such as a shallow trench isolation (STI) structure.

The first semiconductor wiring layer 110 may be on the active surface of the first semiconductor substrate 101 and electrically connected to the first connection pad 140 thereon. The first semiconductor wiring layer 110 may be electrically connected to the first connection member 150 by the first connection pad 140. For example, the first connection pad 140 may include at least one selected from the group consisting of aluminum (Al), copper (Cu), nickel (Ni), tungsten (W), platinum (Pt), and gold (Au).

The first connection member 150 may electrically connect the first semiconductor chip 100 to the interposer 600. The first connection member 150 may include a solder ball attached to the first connection pad 140. The material of the solder ball may include at least one selected from the group consisting of Au, silver (Ag), Cu, tin (Sn), and Al. In some embodiments, the solder ball may be connected to the first connection pad 140 by thermo-compression bonding, ultrasonic bonding, or thermo-sonic bonding that combines thermo-compression bonding and ultrasonic bonding.

The first semiconductor chip 100 may externally receive, through the first connection member 150, a data signal to be stored therein or at least one selected from the group consisting of a control signal for the operation thereof, a power signal, and a ground signal or may provide the data stored therein to the outside thereof through the first connection member 150.

The second semiconductor chip 200 may include a second semiconductor substrate 201, a second semiconductor wiring layer 210, an upper connection pad 220, a through electrode 230, a lower connection pad 240, and a second connection member 250.

The second semiconductor chip 200 may include multiple slices. Each of the multiple slices may be configured as the second semiconductor substrate 201. A plurality of second semiconductor substrates 201 may be stacked in the vertical direction (the Z direction), thereby forming a chip stack. The second semiconductor substrates 201 may be the same or substantially the same as each other. In other words, the second semiconductor chip 200 may have a stack structure of a plurality of slices, which respectively operate as memory chips and allow data merging.

Each of the second semiconductor substrates 201 may have an active surface and an inactive surface facing the active surface. Here, the inactive surface of the topmost second semiconductor substrate 201 may correspond to a top surface 200TS of the second semiconductor chip 200 exposed by the molding layer 500. Each of the second semiconductor substrates 201 other than the topmost second semiconductor substrate 201 may include the through electrode 230 passing therethrough. For example, the through electrode 230 may include a through silicon via (TSV). In some embodiments, all of the second semiconductor substrates 201 may each include the through electrode 230 passing therethrough.

The upper connection pad 220 and the lower connection pad 240 may be electrically connected to the through electrode 230 respectively at the top and bottom of the through electrode 230. The lower connection pad 240 may be electrically connected to the second semiconductor wiring layer 210 on the active surface of each of the second semiconductor substrates 201. The second semiconductor wiring layer 210 may be electrically connected to the second connection member 250 by the lower connection pad 240.

The second connection member 250 that is in contact with the bottommost second semiconductor substrate 201 among the second semiconductor substrates 201 may electrically connect the second semiconductor chip 200 to the interposer 600. The second connection member 250 may include a solder ball attached to the lower connection pad 240.

The second semiconductor chip 200 may externally receive, through the second connection member 250, a data signal to be stored therein or at least one selected from the group consisting of a control signal for the operation thereof, a power signal, and a ground signal or may provide the data stored therein to the outside thereof through the second connection member 250.

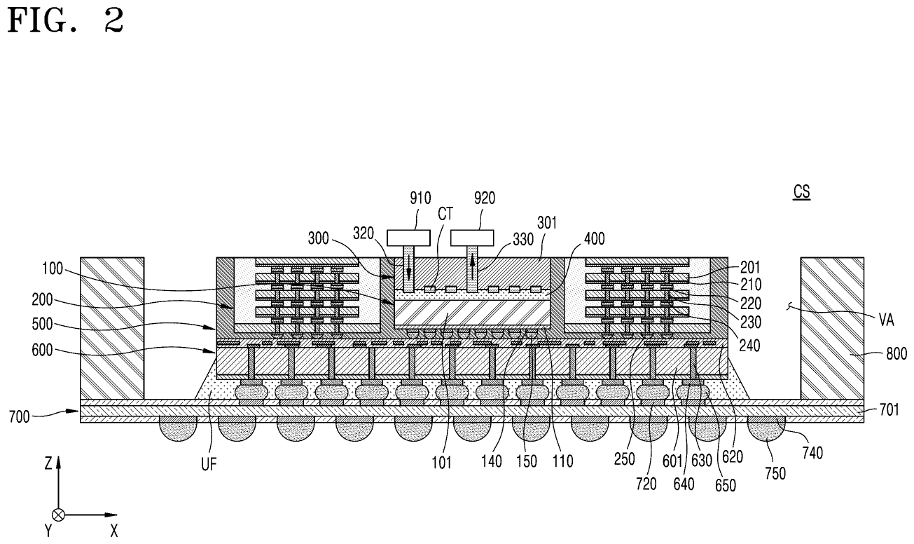

The dummy semiconductor chip 300 may be stacked on the first semiconductor chip 100. The dummy semiconductor chip 300 may include a dummy substrate 301, an inlet 320 through which a cooling fluid CT (in FIG. 2) flows in, an outlet 330 through which the cooling fluid CT flows out, and a cooling channel 340 extending from the inlet 320 to the outlet 330. The cooling channel 340 may provide an internal channel through which the cooling fluid CT (in FIG. 2) may flow. The cooling fluid CT (in FIG. 2) may flow through the cooling channel 340, e.g., the internal channel of the dummy semiconductor chip 300, and thus cool the first semiconductor chip 100.

The dummy semiconductor chip 300 may include a single slice. The single slice may be configured as the dummy substrate 310. For example, the dummy substrate 310 may include a semiconductor material such as silicon. In some embodiments, the dummy semiconductor chip 300 may include only a semiconductor material. For example, the dummy semiconductor chip 300 may be a part of a bare wafer. Alternatively, the dummy semiconductor chip 300 may include multiple slices.

A top surface 300TS of the dummy semiconductor chip 300 may have a flat shape and a bottom surface 300BS of the dummy semiconductor chip 300 may have a concave-convex shape. The top surface 300TS of the dummy semiconductor chip 300 may be coplanar with the top surface 200TS of the second semiconductor chip 200 and a top surface 500TS of the molding layer 500. The bottom surface 300BS of the dummy semiconductor chip 300 may have the cooling channel 340 therein and thus have the concave-convex shape. The vertical thickness of the dummy semiconductor chip 300 may be greater than each of the vertical thickness of the first semiconductor chip 100 and the vertical thickness of the second semiconductor chip 200.

The cooling fluid CT (in FIG. 2) may flow into the cooling channel 340 through the inlet 320 of the dummy semiconductor chip 300. The cooling fluid CT (in FIG. 2) may flow to the outlet 330 through the cooling channel 340. The inlet 320 and the outlet 330 may be above the cooling channel 340. For example, the cooling channel 340 may be at a first level and the inlet 320 and the outlet 330 may be at a second level that is at a higher vertical level than the first level.

Although it is illustrated in FIG. 1C that the planar cross-section of each of the inlet 320 and the outlet 330 has a circular shape, inventive concepts are not limited thereto. For example, the planar cross-section of each of the inlet 320 and/or the outlet 330 may have an oval shape, a polygonal shape, and/or an irregular shape.

As shown in FIGS. 1B and 1C, the cooling channel 340 may overlap the first semiconductor chip 100 of the semiconductor package 10 in the vertical direction (the Z direction). As described above, when the semiconductor package 10 operates, the amount of heat generated in the first semiconductor chip 100 corresponding to a logic chip may be greater than the amount of heat generated in the second semiconductor chip 200 corresponding to a memory chip. Accordingly, when the dummy semiconductor chip 300 is located on the first semiconductor chip 100, heat generated in the first semiconductor chip 100 may be efficiently dissipated to the outside of the semiconductor package 10.

According to a plan view, the dummy semiconductor chip 300 may overlap the first semiconductor chip 100 in the vertical direction (the Z direction) and may be separated from the second semiconductor chip 200 in the horizontal direction (the X direction and/or the Y direction).

As shown in FIGS. 1B and 1C, the outlet 330 may be closer to the center of the top surface 100TS of the first semiconductor chip 100 and/or the center of the top surface 300TS of the dummy semiconductor chip 300 than the inlet 320. For example, according to a plan view, the outlet 330 may overlap the center of the first semiconductor chip 100 and/or the center of the dummy semiconductor chip 300 in the vertical direction (the Z direction) and the inlet 320 may be near the edge of the first semiconductor chip 100 and/or the edge of the dummy semiconductor chip 300. For example, according to a plan view, the inlet 320 may be separated from the center of the first semiconductor chip 100 and/or the center of the dummy semiconductor chip 300 in the horizontal direction (the X direction and/or the Y direction).

For example, according to a plan view, the cooling channel 340 may correspond to a single channel linear extending on the top surface 100TS of the first semiconductor chip 100. For example, the cooling channel 340 may include a plurality of first sub channels, which linearly extend on the first semiconductor chip 100 in the first horizontal direction (the X direction) and are separated from each other in the second horizontal direction (the Y direction) and a plurality of second sub channels, which linearly extend on the first semiconductor chip 100 in the second horizontal direction (the Y direction) and are separated from each other in the first horizontal direction (the X direction). A side of each of the first sub channels may be connected to a side of at least one second sub channel. A side of each of the second sub channels may be connected to a side of at least one first sub channel. In other words, the entirety of the cooling channel 340 may overlap the first semiconductor chip 100 in the vertical direction (the Z direction).

The bonding insulating layer 400 may be on the bottom surface 300BS of the dummy semiconductor chip 300. The bonding insulating layer 400 may be between the first semiconductor chip 100 and the dummy semiconductor chip 300. The bonding insulating layer 400 may cover at least a portion of each of the top surface 100TS of the first semiconductor chip 100 and the bottom surface 300BS of the dummy semiconductor chip 300. In embodiments, the bonding insulating layer 400 may entirely cover the top surface 100TS of the first semiconductor chip 100 and the bottommost surface of the dummy semiconductor chip 300. In other words, the bottom surface and topmost surface of the bonding insulating layer 400 may be in contact with only a semiconductor material. In embodiments, the bonding insulating layer 400 may not cover at least a portion of the top surface 100TS of the first semiconductor chip 100 and/or at least a portion of the bottommost surface of the dummy semiconductor chip 300.

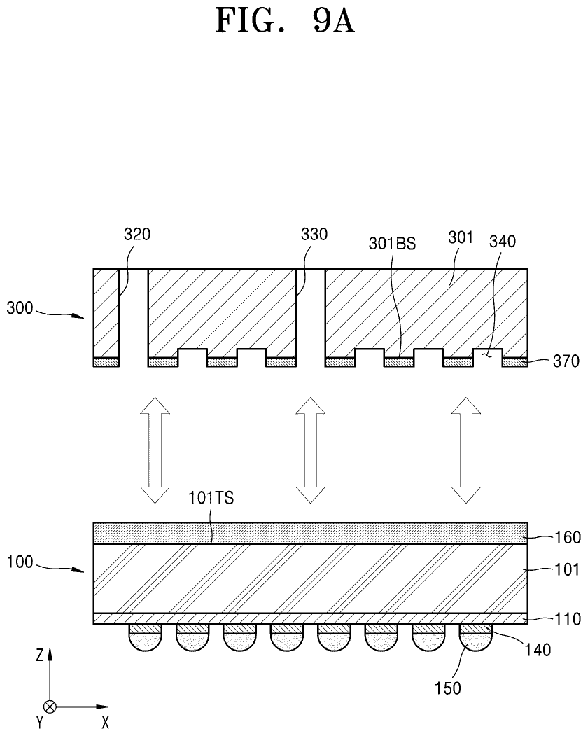

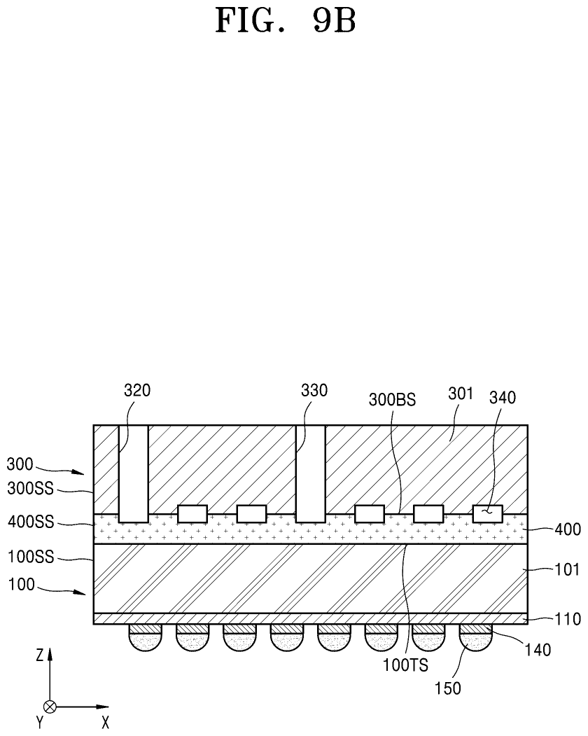

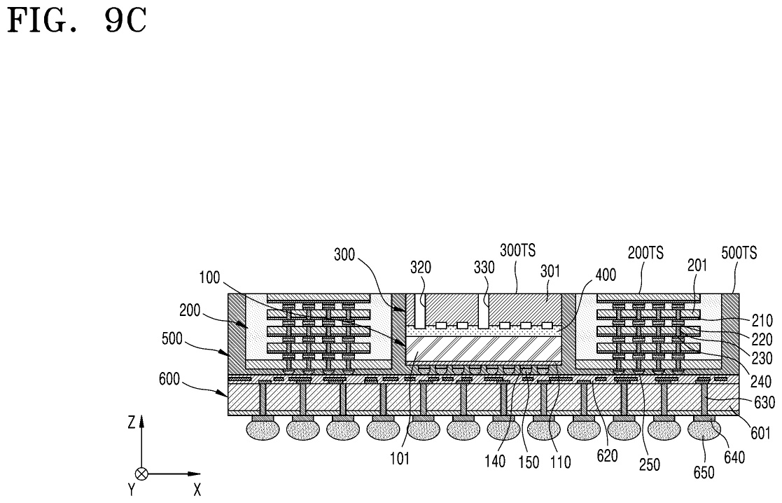

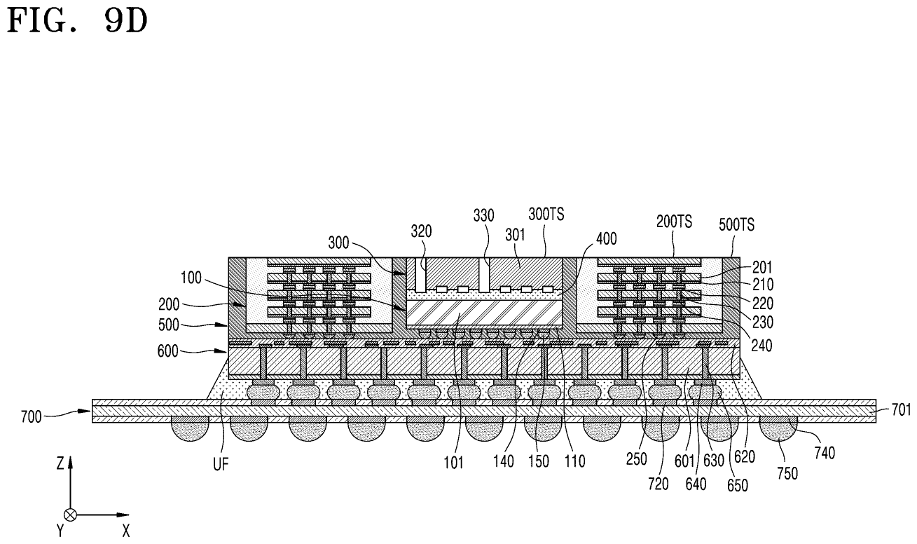

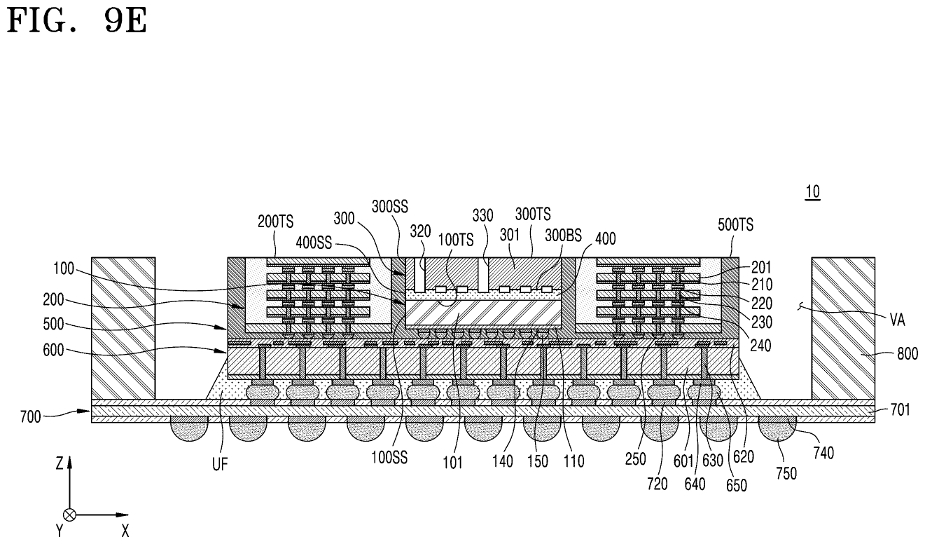

The bonding insulating layer 400 may be formed by respectively forming passivation layers on the top surface 100TS of the first semiconductor chip 100 and the bottom surface 300BS of the dummy semiconductor chip 300, activating the passivation layers facing each other by performing plasma processing and/or wet processing, and performing passivation bonding on the passivation layers to form an integral body through bonding of molecules of the passivation layers. The process of forming the bonding insulating layer 400 is described in detail with reference to FIGS. 9A and 9B. The bonding insulating layer 400 may be an oxide-rich layer.

Only a semiconductor material may be exposed on the bottom surface of the dummy substrate 301. Accordingly, the topmost surface of the bonding insulating layer 400 may be in contact with only the semiconductor material. Neither metal pad nor metal bump may be arranged inside the bonding insulating layer 400. In some embodiments, a metal pad and/or a metal bump may be arranged inside the bonding insulating layer 400.

The bottom surface of the bonding insulating layer 400 may be in contact with the top surface 100TS of the first semiconductor chip 100 and the top surface of the bonding insulating layer 400 may be in contact with at least a portion of the bottom surface 300BS of the dummy semiconductor chip 300. The cooling channel 340 may be in contact with at least a portion of the top surface of the bonding insulating layer 400. The top surface of the bonding insulating layer 400 may have a concave-convex shape and the bottom surface of the bonding insulating layer 400 may have a flat shape.

The topmost surface of the bonding insulating layer 400 may be at a higher vertical level than the bottommost surface of the cooling channel 340. The topmost surface of the bonding insulating layer 400 may also be at a higher vertical level than the bottommost surface of the dummy semiconductor chip 300. The thickness of the bonding insulating layer 400 overlapping the cooling channel 340 in the vertical direction (the Z direction) may be less than the thickness of the bonding insulating layer 400 separated from the cooling channel 340 in the horizontal direction (the X direction and/or the Y direction).

The bonding insulating layer 400 may be aligned with the first semiconductor chip 100 and the dummy semiconductor chip 300 in the vertical direction (the Z direction). For example, a sidewall 400SS of the bonding insulating layer 400 may be aligned and coplanar with a sidewall 100SS of the first semiconductor chip 100 and a sidewall 300SS of the dummy semiconductor chip 300 in the vertical direction (the Z direction).

The bonding insulating layer 400 may limit and/or prevent the cooling fluid CT (in FIG. 2) from penetrating into the first semiconductor chip 100, the second semiconductor chip 200, and/or the molding layer 500. In other words, the bonding insulating layer 400 may be configured to limit and/or prevent the cooling fluid CT (in FIG. 2) from being absorbed or adsorbed by the first semiconductor chip 100, the second semiconductor chip 200, and/or the molding layer 500.

When the bonding insulating layer 400 covers at least a portion of each of the top surface 100TS of the first semiconductor chip 100 and the bottom surface 300BS of the dummy semiconductor chip 300, heat generated in the first semiconductor chip 100 may be efficiently transmitted to the cooling fluid CT (in FIG. 2) through the bonding insulating layer 400.

The bonding insulating layer 400 may include SiO, SiN, SiCN, SiCO, or a polymeric material. The polymeric material may include benzocyclobutene (BCB), polyimide (PI), polybenzoxazole (PBO), silicone, acrylate, or epoxy. For example, the bonding insulating layer 400 may include silicon oxide. For example, the bonding insulating layer 400 may have a thickness of about 100 nm to about 10 μm.

The molding layer 500 may surround the first semiconductor chip 100, the second semiconductor chip 200, and the dummy semiconductor chip 300. In detail, the molding layer 500 may extend along and cover the sidewalls of each of the first semiconductor chip 100, the second semiconductor chip 200, and the dummy semiconductor chip 300. The molding layer 500 may extend along and cover the bottom surface of each of the first and second semiconductor chips 100 and 200. Here, the molding layer 500 may cover neither the top surface 200TS of the second semiconductor chip 200 nor the top surface 300TS of the dummy semiconductor chip 300. Accordingly, the top surface 500TS of the molding layer 500 may be coplanar with the top surface 200TS of the second semiconductor chip 200 and the top surface 300TS of the dummy semiconductor chip 300.

For example, the top surface 500TS of the molding layer 500 may be at a higher vertical level than the top surface 100TS of the first semiconductor chip 100. In other words, the top surface 200TS of the second semiconductor chip 200 may be at a higher vertical level than the top surface 100TS of the first semiconductor chip 100.

The molding layer 500 may protect the first semiconductor chip 100, the second semiconductor chip 200, and the dummy semiconductor chip 300 from external impact, such as shock and contamination. For example, the molding layer 500 may include an epoxy mold compound or resin. The molding layer 500 may be formed by a process, such as compression molding, lamination, or screen printing.

The interposer 600 may be below the first and second semiconductor chips 100 and 200, and may electrically connect the first semiconductor chip 100 to the second semiconductor chip 200. In some embodiments, the interposer 600 may include a silicon substrate 601 and a redistribution structure 620 on the silicon substrate 601. The interposer 600 may also include an interposer through electrode 630, a connection pad 640, and an internal connection terminal 650. The interposer through electrode 630 may be electrically connected to the redistribution structure 620 and may pass through the silicon substrate 601. The connection pad 640 may be below the silicon substrate 601 and electrically connected to the interposer through the interposer through electrode 630. The internal connection terminal 650 may be attached to the connection pad 640.

The package substrate 700 may be below the interposer 600. The package substrate 700 may be formed based on a printed circuit board (PCB), a wafer substrate, a ceramic substrate, a glass substrate, or the like. In embodiments, the package substrate 700 may correspond to a PCB. The package substrate 700 may include a body 701, a bump pad 740 below the body 701, and an external connection terminal 750 attached to the bump pad 740. The semiconductor package 10 may be electrically connected through the external connection terminal 750 to the main board or system board of an external electronic device on which the semiconductor package 10 is mounted.

An underfill UF may be between the interposer 600 and the package substrate 700. The underfill UF may surround the internal connection terminal 650. For example, the underfill UF may include epoxy resin. In some embodiments, a non-conductive film (NCF) may be formed instead of the underfill UF.

The reinforcing structure 800 may be on an outer portion of the top surface of the package substrate 700. The reinforcing structure 800 may be separated from the first semiconductor chip 100, the second semiconductor chip 200, and the dummy semiconductor chip 300 in the horizontal direction (the X direction and/or the Y direction). The reinforcing structure 800 may not overlap the first semiconductor chip 100, the second semiconductor chip 200, and the dummy semiconductor chip 300 in the vertical direction (the Z direction). According to a plan view or a top view, the reinforcing structure 800 may surround the first semiconductor chip 100, the second semiconductor chip 200, the dummy semiconductor chip 300, and the molding layer 500. In other words, the reinforcing structure 800 may have a quadrangular ring shape surrounding the first semiconductor chip 100, the second semiconductor chip 200, the dummy semiconductor chip 300, and the molding layer 500. According to a plan view, the reinforcing structure 800 may extend in contact with four edges of the package substrate 700. The reinforcing structure 800 may have a shape in which four sidewalls respectively extending along four edges of the package substrate 700 are connected to each other. The reinforcing structure 800 may include a metal material, such as Cu, Ni, Al, and/or stainless steel (SUS). The reinforcing structure 800 may be separated from the first and second semiconductor chips 100 and 200, the dummy semiconductor chip 300, and the interposer 600 and may thus form an empty space VA. In other words, the first and second semiconductor chips 100 and 200, the dummy semiconductor chip 300, and the interposer 600 may be accommodated in the empty space VA provided by the reinforcing structure 800.

Because the semiconductor package 10 includes the bonding insulating layer 400 between the first semiconductor chip 100 and the dummy semiconductor chip 300, the adhesion between the first semiconductor chip 100 and the dummy semiconductor chip 300 may increase, thereby increasing the structural reliability of the semiconductor package 10. In addition, because heat transmission from the first semiconductor chip 100 to the dummy semiconductor chip 300 increases, the heat dissipation capability of the semiconductor package 10 may increase.

The bonding insulating layer 400 of the semiconductor package 10 may be formed by passivation bonding, in which a first passivation layer 160 (in FIG. 9A) on the first semiconductor substrate 101 and a second passivation layer 370 (in FIG. 9A) on the dummy substrate 301 undergo plasma processing and/or wet processing so as to be bonded to each other. Because the bonding insulating layer 400 is formed by passivation bonding, the bonding insulating layer 400 may have an excellent waterproof effect and the structural reliability of the semiconductor package 10 may increase.

FIG. 2 a cross-sectional view illustrating a cooling system of a semiconductor package according to an embodiment. FIGS. 1A to IC are also referred to.

Referring to FIG. 2, a cooling system CS may be provided above the semiconductor package 10 and may include a cooling fluid CT, a water-cooled pump 910, and a heat dissipator 920 (e.g. structure including radiator fins).

The cooling fluid CT may be based on ultrapure water. The cooling fluid CT may include ultrapure water and various additives. For example, the additives may include surfactant, corrosion inhibitor, antifreeze, and nanoparticles having thermal conductivity.

The water-cooled pump 910 may be connected to the inlet 320 of the dummy semiconductor chip 300 and the heat dissipator 920 may be connected to the outlet 330 of the dummy semiconductor chip 300. The water-cooled pump 910 and the heat dissipator 920 may be respectively connected to the inlet 320 and the outlet 330 of the dummy semiconductor chip 300 through a piping system.

The operation of the cooling system CS is described in detail below. The arrows in FIG. 2 schematically indicate the movement path of the cooling fluid CT. The cooling fluid CT provided from the water-cooled pump 910 may flow into the inlet 320 of the dummy semiconductor chip 300. Subsequently, the cooling fluid CT may flow through the cooling channel 340 of the dummy semiconductor chip 300 and collect in the heat dissipator 920 connected to the outlet 330 of the dummy semiconductor chip 300.

In general, the internal temperature of the semiconductor package 10 may increase during the operation thereof. In this case, a temperature of the first semiconductor chip 100 may be higher than the temperature of the dummy semiconductor chip 300 and the temperature of the cooling fluid CT. Accordingly, when the cooling fluid CT is provided to the cooling channel 340, heat exchange may occur between the first semiconductor chip 100 and the cooling fluid CT. As a result of the heat exchange, the temperature of the first semiconductor chip 100 may decrease and the temperature of the cooling fluid CT may increase. The cooling fluid CT having the increased temperature may be cooled by the heat dissipator 920 before being used to cool the first semiconductor chip 100.

With the rapid increase in demand for portable devices in the recent electronic products market, electronic components mounted on electronic products have continuously been required to be compact and light. To make electronic components compact and light, a semiconductor package mounted on the electronic components is required to be small in volume and to process a large amount of data. There is also a demand for high integration and single package of semiconductor chips mounted on such a semiconductor package. Accordingly, a system-in-package is used to efficiently arrange semiconductor chips in the limited structure of a semiconductor package. However, in the case of a semiconductor package having a high response speed and a high capacity, problems caused by overheating and thermal fatigue are becoming more serious due to the limited structure of the semiconductor package.

According to embodiments of inventive concepts, the semiconductor package 10 is designed to connect a water-cooled cooling system to an upper portion of the first semiconductor chip 100 such that cooling of the first semiconductor chip 100 may be carried out by direct cooling using the cooling fluid CT, while securing high waterproof performance by having the bonding insulating layer 400 between the first semiconductor chip 100 and the dummy semiconductor chip 300. In addition, the temperature of the first semiconductor chip 100 may be efficiently decreased by arranging the dummy semiconductor chip 300 on the first semiconductor chip 100 having a relatively high temperature.

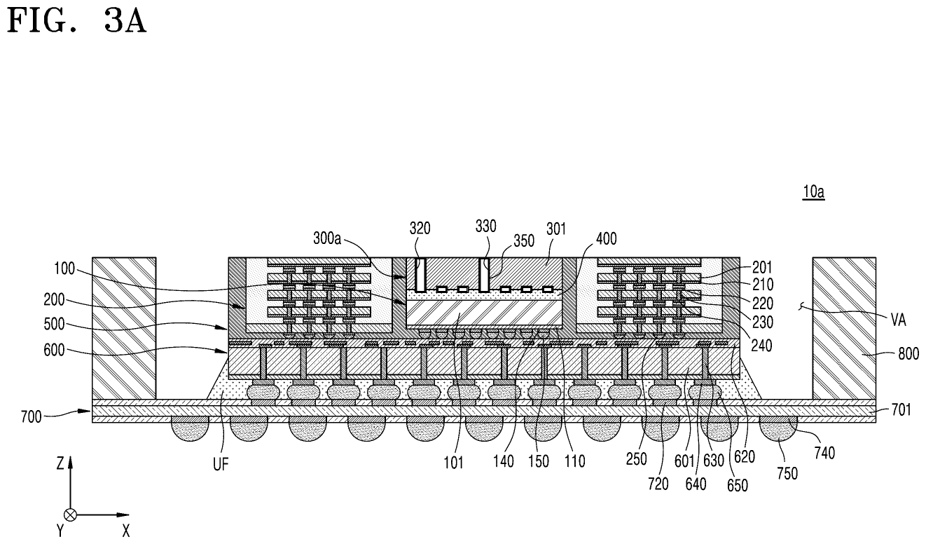

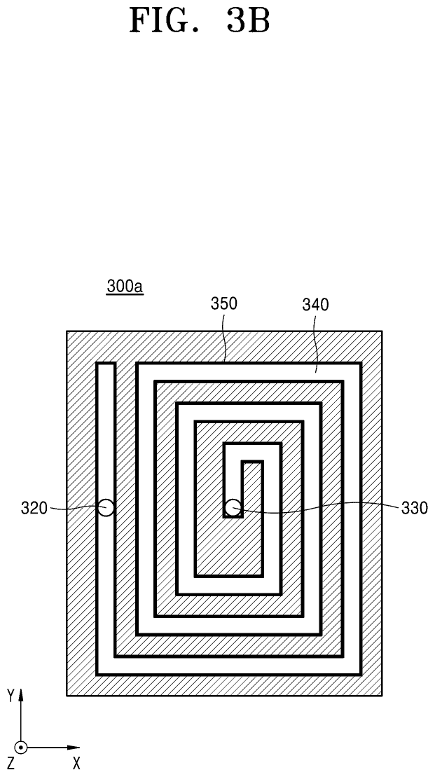

FIG. 3A is a cross-sectional view of a semiconductor package according to an embodiment and FIG. 3B is a plan view of a dummy semiconductor chip according to an embodiment. FIGS. 1A to 2 are also referred to.

Referring to FIGS. 3A and 3B, a semiconductor package 10a may include a first semiconductor chip 100, a second semiconductor chip 200, a dummy semiconductor chip 300a, a molding layer 500, an interposer 600, a package substrate 700, and a reinforcing structure 800. The first semiconductor chip 100, the second semiconductor chip 200, the molding layer 500, the interposer 600, the package substrate 700, and the reinforcing structure 800 of the semiconductor package 10a of FIGS. 3A and 3B are the same or substantially the same as those of the semiconductor package 10 of FIG. 1A, and thus the dummy semiconductor chip 300a is described below.

The dummy semiconductor chip 300a may further include a barrier layer 350 on the inner sidewall of each of (or at least one of) the inlet 320, the outlet 330, and the cooling channel 340. The barrier layer 350 may conformally extend along the inner sidewall of each of the inlet 320, the outlet 330, and the cooling channel 340. The barrier layer 350 may cover the inner sidewall of each of (or at least one of) the inlet 320, the outlet 330, and the cooling channel 340.

The barrier layer 350 may limit and/or prevent the cooling fluid CT from penetrating into the dummy substrate 301. In other words, the barrier layer 350 may limit and/or prevent the cooling fluid CT from being absorbed or adsorbed by the dummy substrate 301. The barrier layer 350 may include a waterproof material, such as metal or silicon (Si). For example, the barrier layer 350 may include Ti, Cu, Ni, Au, Ag, Al, Si, or a combination thereof. For example, the barrier layer 350 may include a first layer including Ti and a second layer including at least one selected from the group consisting of Cu, Ni, and Si.

The barrier layer 350 may include a material, e.g., metal, which has a high thermal conductivity, thereby facilitating cooling of the first semiconductor chip 100 using the cooling fluid CT. Heat may be exchanged between the cooling fluid CT and the dummy semiconductor chip 300a through the barrier layer 350. For example, the barrier layer 350 may have a thickness of about 100 nm to about 10 μm.

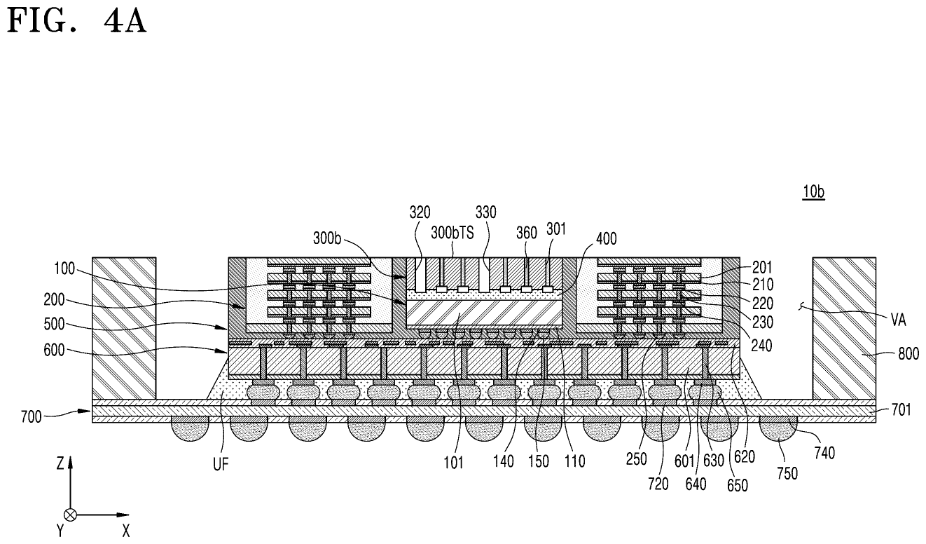

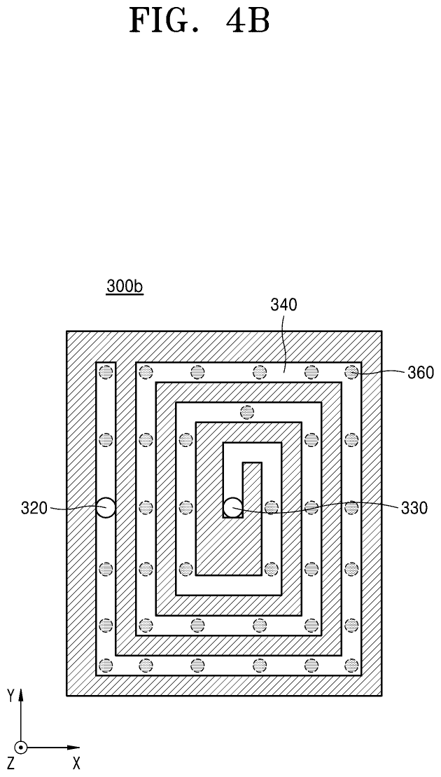

FIG. 4A is a cross-sectional view of a semiconductor package according to an embodiment and FIG. 4B is a plan view of a dummy semiconductor chip according to an embodiment. FIGS. 1A to 2 are also referred to.

Referring to FIGS. 4A and 4B, a dummy semiconductor chip 300b may include a dummy semiconductor substrate 301, an inlet 320, an outlet 330, a cooling channel 340, and a dummy through electrode 360. The semiconductor substrate 301, the inlet 320, the outlet 330, and the cooling channel 340 of the dummy semiconductor chip 300b of FIG. 4A are the same or substantially the same as those of the dummy semiconductor chip 300 of FIG. 1A, and thus only the dummy through electrode 360 is described below.

The dummy through electrode 360 may penetrate the dummy substrate 301 in the vertical direction (the Z direction). For example, the dummy through electrode 360 may include a TSV. The dummy through electrode 360 may include a material having a high thermal conductivity. For example, the thermal conductivity of the dummy through electrode 360 may be higher than that of the dummy substrate 301. For example, the dummy through electrode 360 may include metal.

The bottom surface of the dummy through electrode 360 may be in contact with the cooling channel 340 and the top surface of the dummy through electrode 360 may be at the same vertical level as the top surface 300TS of the dummy semiconductor chip 300b. The dummy through electrode 360 may enable the cooling fluid CT in the cooling channel 340 to easily exchange heat with the outside of the dummy semiconductor chip 300b. In other words, the dummy through electrode 360 may enable the cooling fluid CT in the cooling channel 340 to easily exchange heat with the outside of the semiconductor package 10b. In other words, the dummy through electrode 360 may facilitate cooling of the first semiconductor chip 100 using the cooling fluid CT.

According to a plan view, the dummy through electrode 360 may overlap the cooling channel 340 in the vertical direction (the Z direction). The dummy through electrode 360 may be separated from the inlet 320 and the outlet 330 in the horizontal direction (the X direction and/or the Y direction). In some embodiments, at least one dummy through electrode 360 may not overlap the cooling channel 340 in the vertical direction (the Z direction) and may be separated from the cooling channel 340 in the horizontal direction (the X direction and/or the Y direction).

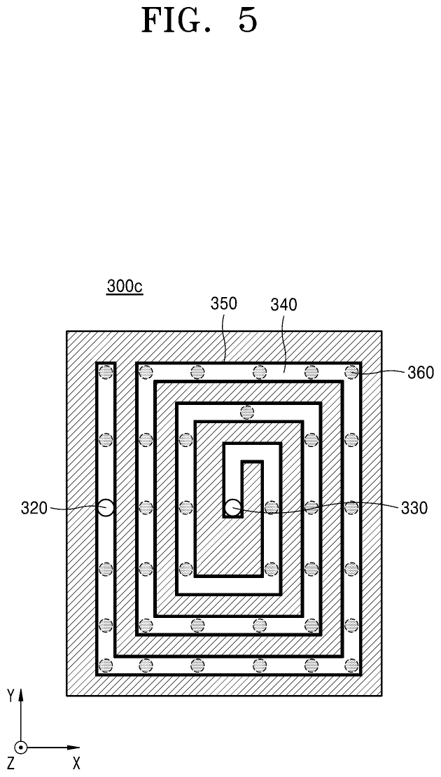

FIG. 5 is a plan view of a dummy semiconductor chip according to an embodiment. FIGS. 1A to 4B are also referred to.

Referring to FIG. 5, a dummy semiconductor chip 300c may further include plurality of inlets 320, a plurality of outlets 330, the cooling channel 340, the barrier layer 350, and the dummy through electrode 360. The barrier layer 350 on the inner sidewall of each of (or at least one of) the inlet 320, the outlet 330, and the cooling channel 340. The barrier layer 350 may conformally extend along the inner sidewall of each of the inlet 320, the outlet 330, and the cooling channel 340. The barrier layer 350 may cover the inner sidewall of each of (or at least one of) the inlet 320, the outlet 330, and the cooling channel 340. The dummy through electrode 360 may penetrate the dummy substrate 301 in the vertical direction (the Z direction). The dummy through electrode 360 may facilitate cooling of the first semiconductor chip 100 using the cooling fluid CT. According to a plan view, the dummy through electrode 360 may overlap the cooling channel 340 in the vertical direction (the Z direction). The dummy through electrode 360 may be separated from the inlet 320, the outlet 330 and the barrier layer 350 in the horizontal direction (the X direction and/or the Y direction). In some embodiments, at least one dummy through electrode 360 may not overlap the cooling channel 340 in the vertical direction (the Z direction) and may be separated from the cooling channel 340 in the horizontal direction (the X direction and/or the Y direction).

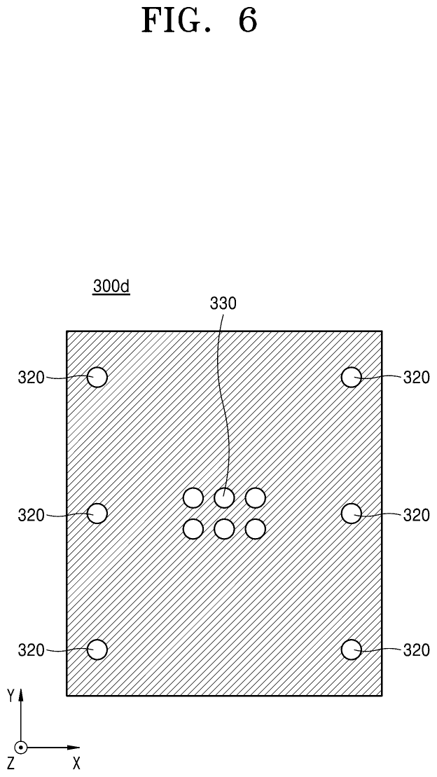

FIG. 6 is a plan view of a dummy semiconductor chip according to an embodiment. FIGS. 1A to 2 are also referred to. To clearly show the arrangement relationship between the inlet 320 and the outlet 330, the cooling channel 340 is omitted from FIG. 6.

Referring to FIG. 6, a dummy semiconductor chip 300d may include a plurality of inlets 320 and a plurality of outlets 330. According to a plan view, the inlets 320 may be near the edge of each of the first semiconductor chip 100 and the dummy semiconductor chip 300d and the outlets 330 may be near the center of each of the first semiconductor chip 100 and the dummy semiconductor chip 300d.

The cooling fluid CT may be provided to the cooling channel 340 through the inlets 320. The cooling fluid CT may be discharged to the outside of the dummy semiconductor chip 300d through the outlets 330.

The locations of the inlets 320 and the outlets 330 are not limited to those shown in FIG. 6. For example, the inlets 320 may be near the center of each of the first semiconductor chip 100 and the dummy semiconductor chip 300d and the outlets 330 may be near the edge of each of the first semiconductor chip 100 and the dummy semiconductor chip 300d.

Although not shown in FIG. 6, the cooling channel 340 may be connected to the inlets 320 and the outlets 330. For example, the cooling channel 340 may overlap the inlets 320 and the outlets 330 in the vertical direction (the Z direction).

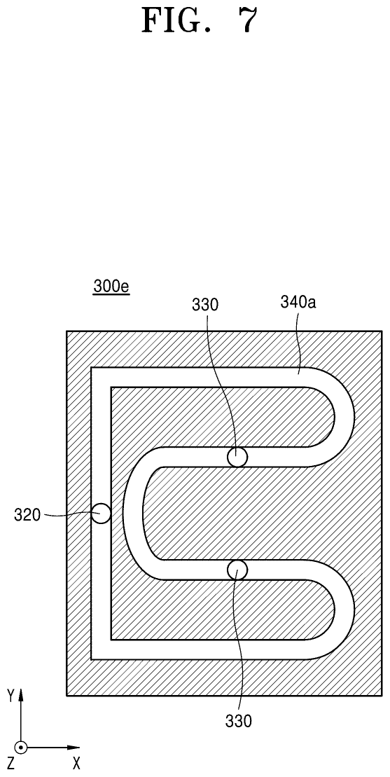

FIG. 7 is a plan view of a dummy semiconductor chip according to an embodiment. FIGS. 1A to 2 are also referred to.

Referring to FIG. 7, a dummy semiconductor chip 300e may include a cooling channel 340a that is a single channel extending in a serpentine shape on the top surface 100TS of the first semiconductor chip 100. For example, the cooling channel 340a may include a first sub channel linearly extending in the second horizontal direction (the Y direction) on the first semiconductor chip 100, a plurality of second sub channels linearly extending in the first horizontal direction (the X direction) on the first semiconductor chip 100 and being separated from each other in the second horizontal direction (the Y direction), and a plurality of connection channels connecting the first sub channel and the second sub channels to one another.

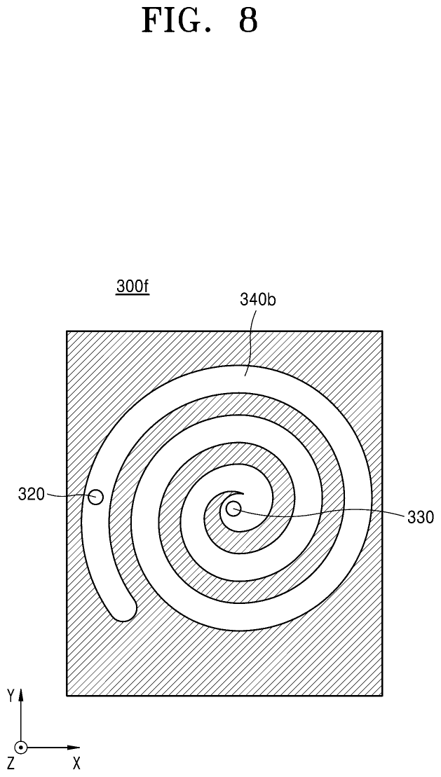

FIG. 8 is a plan view of a dummy semiconductor chip according to an embodiment. FIGS. 1A to 2 and 6 are also referred to.

Referring to FIG. 8, a dummy semiconductor chip 300f may include a cooling channel 340b extending in a spiral shape on the top surface 100TS of the first semiconductor chip 100. According to a plan view, the inlet 320 and the outlet 330 may overlap the cooling channel 340b in the vertical direction (the Z direction).

Although various shapes and locations of the inlet 320, the outlet 330, and the cooling channels 340, 340a, and 340b have been described with reference to FIGS. 1C to 2, and 7, inventive concepts are not limited thereto. For example, there may be a plurality of inlets 320 and/or outlets 330 and the location of each of the inlets 320 and/or the outlets 330 may vary. Also, there may a plurality of cooling channels 340, 340a, or 340b and the locations and shapes thereof may vary. For example, according to a plan view, the cooling channels 340, 340a, and 340b may be arranged near a hot spot of the first semiconductor chip 100.

FIGS. 9A to 9E are cross-sectional views of stages in a method of manufacturing a semiconductor package, according to an embodiment. A method of manufacturing the semiconductor package 10 described with reference to FIGS. 1A to IC and a method of configuring the cooling system CS of the semiconductor package 10 of FIG. 2 are described below with reference to FIGS. 9A to 9E.

Referring to FIGS. 9A and 9B, the first semiconductor chip 100 and the dummy semiconductor chip 300 may be prepared. The first semiconductor chip 100 and the dummy semiconductor chip 300 may perform different functions from each other. The first semiconductor chip 100 may include a logic chip and perform various kinds of signal processing. The dummy semiconductor chip 300 may include the inlet 320, the outlet 330, and the cooling channel 340 and enable heat generated in the first semiconductor chip 100 to be efficiently dissipated to the outside of the semiconductor package 10.

The first semiconductor chip 100 may include the first semiconductor substrate 101, the first semiconductor wiring layer 110, the first connection pad 140, the first connection member 150, and a first passivation layer 160. The first passivation layer 160 may be formed on the top surface of the first semiconductor substrate 101. The first passivation layer 160 may cover a top surface 101TS of the first semiconductor substrate 101 and may have substantially flat top and bottom surfaces to have a substantially uniform thickness. For example, the first passivation layer 160 may entirely cover the top surface 101TS of the first semiconductor substrate 101.

The dummy semiconductor chip 300 may include the dummy substrate 301, the inlet 320, the outlet 330, the cooling channel 340, and a second passivation layer 370. The second passivation layer 370 may be formed on a bottom surface 301BS of the dummy substrate 301. For example, the second passivation layer 370 may be separated from the cooling channel 340 in the horizontal direction (the X direction and/or the Y direction). The second passivation layer 370 may not overlap the cooling channel 340 in the vertical direction (the Z direction).

The first and second passivation layers 160 and 370 may include SiO, SiN, SiCN, SiCO, or a polymeric material. The polymeric material may include BCB, PI, PBO, silicone, acrylate, or epoxy. For example, the first and second passivation layers 160 and 370 may include silicon oxide.

Each of the first and second passivation layers 160 and 370 may be respectively formed on the top surface 101TS of the first semiconductor substrate 101 and the bottom surface 301BS of the dummy substrate 301 by using chemical vapor deposition (CVD), physical vapor deposition (PVD), atomic layer deposition (ALD), and/or plasma-enhanced CVD.

Thereafter, plasma processing and/or wet processing may be performed on the first and second passivation layers 160 and 370. When plasma processing and/or wet processing is performed on the first and second passivation layers 160 and 370, diffusion, chemical reaction, and intermolecular bonding may be induced in each of the first and second passivation layers 160 and 370 so that the first and second passivation layers 160 and 370 may be bonded to each other. For example, when plasma processing and/or wet processing is performed on the first and second passivation layers 160 and 370, a dangling bond, e.g., an incomplete bond, may be formed in each of the first and second passivation layers 160 and 370. The respective dangling bonds of the first and second passivation layers 160 and 370 may be bonded to each other so that the first and second passivation layers 160 and 370 are bonded to each other, thereby forming the bonding insulating layer 400. For example, the —OH functional group on the top surface of the first passivation layer 160 may be bonded to the —OH functional group on the bottom surface of the second passivation layer 370 via hydrogen bonding. In this case, the bonding insulating layer 400 may be an oxide-rich layer.

The bonded first and second passivation layers 160 and 370 may integrally form the bonding insulating layer 400. Accordingly, the bonding insulating layer 400 may be formed between the first semiconductor chip 100 and the dummy semiconductor chip 300.

The bottom surface of the bonding insulating layer 400 may be in contact with the top surface 100TS of the first semiconductor chip 100 and the top surface of the bonding insulating layer 400 may be in contact with at least a portion of the bottom surface 300BS of the dummy semiconductor chip 300. The cooling channel 340 may be in contact with at least a portion of the top surface of the bonding insulating layer 400. The top surface of the bonding insulating layer 400 may have a concave-convex shape and the bottom surface of the bonding insulating layer 400 may have a flat shape.

The topmost surface of the bonding insulating layer 400 may be at a higher vertical level than the bottommost surface of the cooling channel 340. The topmost surface of the bonding insulating layer 400 may be at a higher vertical level than the bottommost surface of the dummy semiconductor chip 300. The thickness of the bonding insulating layer 400 overlapping the cooling channel 340 in the vertical direction (the Z direction) may be less than the thickness of the bonding insulating layer 400 separated from the cooling channel 340 in the horizontal direction (the X direction and/or the Y direction).

The bonding insulating layer 400 may be aligned with the first semiconductor chip 100 and the dummy semiconductor chip 300 in the vertical direction (the Z direction). For example, a sidewall 400SS of the bonding insulating layer 400 may be aligned and coplanar with the sidewall 100SS of the first semiconductor chip 100 and the sidewall 300SS of the dummy semiconductor chip 300 in the vertical direction (the Z direction).

Referring to FIG. 9C, the first semiconductor chip 100, the second semiconductor chip 200, and the dummy semiconductor chip 300 may be arranged on the interposer 600. For example, the first semiconductor chip 100 and the second semiconductor chip 200 may be separated from each other in the horizontal direction (the X direction and/or the Y direction). The top surface 200TS of the second semiconductor chip 200 may be coplanar with the top surface 300TS of the dummy semiconductor chip 300.

After the first semiconductor chip 100, the second semiconductor chip 200, and the dummy semiconductor chip 300 are mounted on the interposer 600, and the molding layer 500 may be formed to surround the first semiconductor chip 100, the second semiconductor chip 200, and the dummy semiconductor chip 300.

The molding layer 500 may expose the top surface 200TS of the second semiconductor chip 200 and the top surface 300TS of the dummy semiconductor chip 300. Accordingly, the top surface 500TS of the molding layer 500 may be coplanar with the top surface 200TS of the second semiconductor chip 200 and the top surface 300TS of the dummy semiconductor chip 300.

The interposer 600 may electrically connect the first semiconductor chip 100 to the second semiconductor chip 200. An internal connection terminal 650 may be formed below the interposer 600.

Referring to FIG. 9D, the interposer 600 having the first and second semiconductor chips 100 and 200 mounted thereon may be arranged on the package substrate 700.

The interposer may be arranged on the package substrate 700 such that the internal connection terminal 650 below the interposer 600 is electrically connected to the top surface of the package substrate 700.

Thereafter, the underfill UF may be formed between the interposer 600 and the package substrate 700. The underfill UF may be between the interposer 600 and the package substrate 700 to surround the internal connection terminal 650.

The package substrate 700 may include a PCB. The body 701 of the PCB may be usually formed by forming a thin film by compressing a polymeric material such as thermosetting resin, epoxy resin such as flame retardant 4 (FR-4), bismaleimide triazine (BT), or an Ajinomoto build-up film (ABF), or phenol resin to a certain thickness, disposing a copper foil on each of opposite surfaces of the thin film, and forming a wiring through patterning, wherein the wiring is a transmission path of an electrical signal.

The PCB may be divided into a single-layer PCB having a wiring on one side thereof and a double-layer PCB having a wiring on each of both sides thereof. A multi-layer PCB may be formed by forming at least three layers of copper foil by using an insulator called prepreg and forming at least three wirings according to the number of layers of copper foil.

Referring to FIG. 9E, the reinforcing structure 800 may be arranged on the package substrate 700. The reinforcing structure 800 may have a quadrangular ring shape and may be located on an outer portion of the top surface of the package substrate 700. The reinforcing structure 800 may not overlap the first semiconductor chip 100, the second semiconductor chip 200, and the dummy semiconductor chip 300 in the vertical direction (the Z direction). According to a plan view or a top view, the reinforcing structure 800 may surround the first semiconductor chip 100, the second semiconductor chip 200, the dummy semiconductor chip 300, and the molding layer 500.

The reinforcing structure 800 may extend in contact with four edges of the package substrate 700. The reinforcing structure 800 may have a shape in which four sidewalls respectively extending along four edges of the package substrate 700 are connected to each other. The reinforcing structure 800 may include a metal material, such as Cu, Ni, Al, and/or SUS.

Referring to FIG. 2, to form the cooling system CS of the semiconductor package 10, the water-cooled pump 910 may be connected to the inlet 320 of the dummy semiconductor chip 300 and the heat dissipator 920 may be connected to the outlet 330 of the dummy semiconductor chip 300. The water-cooled pump 910 may be connected to the inlet 320 of the dummy semiconductor chip 300 through a pipe and may provide the cooling fluid CT to the inlet 320 of the dummy semiconductor chip 300. The heat dissipator 920 may be connected to the outlet 330 of the dummy semiconductor chip 300 through a pipe and may collect and cool the cooling fluid CT flowing out through the outlet 330 of the dummy semiconductor chip 300. The cooling fluid CT provided from the water-cooled pump 910 may flow along a passage in the semiconductor package 10 to cool the semiconductor package 10 and then collect in the heat dissipator 920.

While inventive concepts has been particularly shown and described with reference to embodiments thereof, it will be understood that various changes in form and details may be made therein without departing from the spirit and scope of the following claims.

What is claimed is:

1. A semiconductor package comprising:
a semiconductor chip;
a dummy semiconductor chip on the semiconductor chip; and
a bonding insulating layer between the semiconductor chip and the dummy semiconductor chip, the bonding insulating layer attaching the semiconductor chip to the dummy semiconductor chip, wherein
the dummy semiconductor chip includes a cooling channel extending from an inlet to an outlet,
the inlet is in fluid communication with the outlet through the cooling channel,
the inlet is configured to allow a cooling fluid to flow in,
the outlet is configured to allow the cooling fluid to flow out, and
a top surface of the bonding insulating layer has a concave-convex shape.

2. The semiconductor package of claim 1, wherein at least a portion of the top surface of the bonding insulating layer is in contact with the cooling channel.

3. The semiconductor package of claim 1, wherein
a thickness of a part of the bonding insulating layer overlapping the cooling channel in a vertical direction is less than a thickness of a portion the bonding insulating layer separated from the cooling channel in a horizontal direction.

4. The semiconductor package of claim 1, further comprising:
a barrier layer on at least one of an inner sidewall of the inlet, an inner sidewall of the outlet, or an inner sidewall of the cooling channel.

5. The semiconductor package of claim 1, further comprising:
a plurality of dummy through electrodes penetrating the dummy semiconductor chip in a vertical direction.

6. The semiconductor package of claim 5, wherein at least one of the plurality of dummy through electrodes overlaps the cooling channel in the vertical direction.

7. The semiconductor package of claim 1, wherein, in a plan view,
the outlet is closer to a center of a top surface of the semiconductor chip than the inlet.

8. The semiconductor package of claim 1, wherein
the bonding insulating layer includes at least one of silicon oxide, SiN, SiCN, benzocyclobutene (BCB), polyimide (PI), polybenzoxazole (PBO), silicone, acrylate, or epoxy.

9. A semiconductor package comprising:
an interposer;
a first semiconductor chip on the interposer;
at least one second semiconductor chip on the interposer and separated from the first semiconductor chip in a horizontal direction;
a dummy semiconductor chip on the first semiconductor chip; and
a bonding insulating layer between the first semiconductor chip and the dummy semiconductor chip, the bonding insulating layer attaching the first semiconductor chip to the dummy semiconductor chip, wherein
the dummy semiconductor chip includes a cooling channel extending from an inlet to an outlet,
the inlet is in fluid communication with the outlet through the cooling channel,
the inlet is configured to allow a cooling fluid to flow in,
the outlet is configured to allow the cooling fluid to flow out, and
a bottom surface of the cooling channel is in contact with at least a portion of a top surface of the bonding insulating layer.

10. The semiconductor package of claim 9, further comprising:
a barrier layer on an inner sidewall of at least one of the inlet, the outlet, or the cooling channel; and
a plurality of dummy through electrodes penetrating the dummy semiconductor chip in a vertical direction, wherein
the barrier layer includes at least one of metal or silicon, and
the plurality of dummy through electrodes include metal.

11. The semiconductor package of claim 10, wherein,
in a plan view, each of the plurality of dummy through electrodes is separated from the inlet and the outlet in the horizontal direction and overlaps the cooling channel in the vertical direction.

12. The semiconductor package of claim 9, wherein
a side surface of the first semiconductor chip, a side surface of the dummy semiconductor chip, and a side surface of the bonding insulating layer are aligned with one another in a vertical direction.

13. The semiconductor package of claim 9, wherein
the top surface of the bonding insulating layer has a concave-convex shape, and
a topmost surface of the bonding insulating layer and a bottom surface of the bonding insulating layer each are in contact with only a semiconductor material.

14. The semiconductor package of claim 9, wherein
a horizontal area of the bonding insulating layer in contact with a top surface of the first semiconductor chip is larger than a horizontal area of the bonding insulating layer in contact with a bottom surface of the dummy semiconductor chip.

15. A semiconductor package comprising:
a package substrate;
an interposer on the package substrate;
a first semiconductor chip on the interposer;
at least one second semiconductor chip on the interposer and separated from the first semiconductor chip in a horizontal direction;
a dummy semiconductor chip on the first semiconductor chip;
a bonding insulating layer between the first semiconductor chip and the dummy semiconductor chip, the bonding insulating layer attaching the first semiconductor chip to the dummy semiconductor chip; and
a molding layer on the interposer, the molding layer surrounding the first semiconductor chip, the at least one second semiconductor chip, the dummy semiconductor chip, and the bonding insulating layer, wherein
the dummy semiconductor chip includes a cooling channel extending from an inlet to an outlet,
the inlet is in fluid communication with the outlet through the cooling channel,
the inlet is configured to allow a cooling fluid to flow in,
the outlet is configured to allow the cooling fluid to flow out, and
a top surface of the bonding insulating layer has a concave-convex shape.

16. The semiconductor package of claim 15, wherein
a bottom surface of the bonding insulating layer has a flat shape, and
a topmost surface of the bonding insulating layer is at a higher vertical level than a bottommost surface of the dummy semiconductor chip.

17. The semiconductor package of claim 15, wherein the bonding insulating layer entirely covers a top surface of the first semiconductor chip and a bottommost surface of the dummy semiconductor chip.

18. The semiconductor package of claim 15, wherein
the dummy semiconductor chip is a part of a bare wafer including a semiconductor material, and
a topmost surface of the bonding insulating layer is in contact with only the semiconductor material.

19. The semiconductor package of claim 15, wherein
a top surface of the at least one second semiconductor chip, a top surface of the dummy semiconductor chip, and a top surface of the molding layer are coplanar with one another, and
a top surface of the first semiconductor chip is at a lower vertical level than the top surface of the molding layer.

20. The semiconductor package of claim 15, wherein
the bonding insulating layer is formed by passivation bonding allowing respective molecules of a plurality of heated and activated passivation layers to be bonded to each other.
